(19) United States
(12) Patent Application Publication
(10) Pub. No.: US 2015/0084711 A1
(43) Pub. Date: Mar. 26, 2015

(54) OSCILLATION CIRCUIT, ELECTRONIC APPARATUS, MOVING OBJECT, AND METHOD FOR MANUFACTURING OSCILLATION CIRCUIT

(71) Applicant: Seiko Epson Corporation, Tokyo (JP)

(72) Inventor: Yosuke ITASAKA, Tatsuno (JP)

(21) Appl. No.: 14/486,079

(22) Filed: Sep. 15, 2014

(30) Foreign Application Priority Data
Sep. 20, 2013 (JP) 2013-195282

(51) Int. Cl. H03L 7/02; H03B 5/30

(52) U.S. Cl. CPC H03L 7/02; H03B 5/30
USPC 331/36 C

(57) ABSTRACT

An oscillation circuit includes an oscillation amplifier circuit that causes an oscillating element to oscillate to generate an oscillation signal, and a correction circuit connected with the oscillation amplifier circuit. At least a power supply voltage is input to the oscillation amplifier circuit. The oscillation amplifier circuit has a frequency variation characteristic that the frequency of the oscillation signal varies in response to variations in the power supply voltage. The power supply voltage is input to the correction circuit. The correction circuit corrects the frequency variation characteristic by using variations in the power supply voltage. The correction circuit may include a first variable capacitance element, and the first variable capacitance element may have a capacitance-voltage characteristic by which the frequency variation characteristic is reduced.

### BACKGROUND

1. Technical Field

The present invention relates to an oscillation circuit, an electronic apparatus, a moving object, and a method for manufacturing an oscillation circuit.

2. Related Art

In an oscillation circuit, a method in which a constant voltage is generated with a regulator circuit and the constant voltage is applied to the oscillation circuit is mainly used for suppressing the influence of variations in external power supply (for example, refer to FIG. 1 in JP-A-2012-039348).

In recent years, however, lower voltage and lower consumption current are required with the demand of lower power consumption, and the difference between a power supply voltage and a regulator voltage is narrowed. Therefore, the stability in the operation of the regulator circuit is deteriorated, and the regulator voltage is liable to be affected by variations in power supply voltage. Many oscillation circuits include a variable capacitance element (also referred to as a varactor) to make the frequency of an oscillation signal (hereinafter also referred to as an oscillation frequency) variable. However, when the regulator voltage varies, a voltage to be applied to, for example, the variable capacitance element also varies, causing a problem of variations in oscillation frequency.

In the invention disclosed in JP-A-2008-004038, a monitoring circuit monitors variations in regulator voltage, and when the regulator voltage varies, a voltage raised by a boost circuit can be supplied again to the regulator circuit to thereby keep the regulator voltage constant.

However, in the monitoring circuit and the boost circuit for the regulator voltage as in the invention disclosed in JP-A-2008-004038, the boost circuit is affected by variations in power supply voltage when the difference between the power supply voltage and the regulator voltage is narrow. Therefore, the voltage generated in the boost circuit also varies with the variations in power supply voltage. Moreover, preparing the monitoring circuit and the boost circuit for the regulator voltage as in the invention disclosed in JP-A-2008-004038 involves a problem of an increase in consumption current or circuit area. Thus, for example, a method for stabilizing the frequency even when variations in the voltage of the boost circuit or the like occur with the variations in power supply voltage, or a method for stabilizing the oscillation frequency even when the variations in power supply voltage occur without adding the monitoring circuit or the like for the regulator voltage is required.

### SUMMARY

An advantage of some aspects of the invention is to provide an oscillation circuit that can reduce variations in oscillation frequency due to variations in power supply voltage without necessarily adding a circuit for monitoring a voltage, an electronic apparatus, a moving object, a method for manufacturing an oscillation circuit, and the like.

The invention can be implemented as the following forms or application examples.

### APPLICATION EXAMPLE 1

An oscillation circuit according to this application example includes: an oscillation amplifier circuit that generates an oscillation signal and has a frequency variation characteristic that the frequency of the oscillation signal varies in response to variations in power supply voltage; and a correction circuit that corrects the frequency variation characteristic with variations in the power supply voltage.

The oscillation circuit according to this application example includes the oscillation amplifier circuit and the correction circuit. The oscillation amplifier circuit causes an oscillating element such as, for example, a quartz crystal resonator to oscillate to generate the oscillation signal, and the power supply voltage is input to the oscillation amplifier circuit. The oscillation amplifier circuit has the frequency variation characteristic that the frequency of the oscillation signal (oscillation frequency) varies in response to variations in the power supply voltage (for example, when the power supply voltage decreases, the oscillation frequency increases). The correction circuit has a characteristic opposite to the frequency variation characteristic (for example, when the power supply voltage decreases, the correction circuit reduces the oscillation frequency). With the use of variations in the power supply voltage, the correction circuit can correct the frequency variation characteristic of the oscillation amplifier circuit. Thus, even when the power supply voltage varies, the correction circuit reduces variations in oscillation frequency in the oscillation amplifier circuit. Therefore, the variations in oscillation frequency can be reduced. In this case, the correction circuit does not monitor the power supply voltage, and therefore does not cause a problem of an increase in consumption current or circuit area. Moreover, for example, even with a circuit configuration including a monitoring circuit and a boost circuit for a regulator voltage, when the oscillation frequency changes with variations in the voltage of the boost circuit due to variations in the power supply voltage, variations in oscillation frequency can be reduced with the use of the correction circuit.

### APPLICATION EXAMPLE 2

In the oscillation circuit according to the application example described above, the correction circuit may include a first variable capacitance element, and the first variable capacitance element may have a capacitance-voltage characteristic by which the frequency variation characteristic is reduced in response to variations in the power supply voltage.

According to the oscillation circuit according to this application example, the correction circuit includes the first variable capacitance element. In many cases, the frequency variation characteristic reflects changes in the capacitance of the variable capacitance element included in the oscillation amplifier circuit due to variations in the power supply voltage. Therefore, the correction circuit can favorably reduce the frequency variation characteristic by using the capacitance-voltage characteristic (also referred to as a C-V characteristic) of the first variable capacitance element.

### APPLICATION EXAMPLE 3

In the oscillation circuit according to the application example described above, the oscillation amplifier circuit may include a second variable capacitance element, one end of the second variable capacitance element may be electrically connected with the oscillation amplifier circuit, and the first variable capacitance element may be controlled so that changes in the capacitance thereof are opposite to variations in the capacitance of the second variable capacitance element due to variations in the power supply voltage.

According to the oscillation circuit according to this application example, the oscillation amplifier circuit includes the second variable capacitance element whose one end is electrically connected with the oscillation amplifier circuit. Therefore, the frequency variation characteristic strongly reflects changes in the capacitance of the second variable capacitance element. Thus, by setting the capacitance-voltage characteristic of the first variable capacitance element so as to reduce variations in the capacitance of the second variable capacitance element, the frequency variation characteristic can be favorably reduced. When, for example, the oscillation circuit is made into an integrated circuit (IC), the electrical connection with the oscillation amplifier circuit includes a connection via a connection terminal (hereinafter referred to simply as a terminal).

### APPLICATION EXAMPLE 4 AND APPLICATION EXAMPLE 5

In the oscillation circuit according to the application example described above, the power supply voltage may be applied to one end of the first variable capacitance element.

According to the oscillation circuit according to these application examples, the power supply voltage is applied to the one end of the first variable capacitance element. Therefore, compared to the case where, for example, a regulator voltage is applied, the power supply voltage can be transmitted to the first variable capacitance element without reducing variations in the power supply voltage. Thus, since there is no need to increase the capacitance variable sensitivity of the first variable capacitance element, the noise resistance can be increased.

### APPLICATION EXAMPLE 6

In the oscillation circuit according to the application example described above, the oscillation amplifier circuit may include a second variable capacitance element, the correction circuit may generate a second control voltage based on the power supply voltage and a first control voltage, one end of the second variable capacitance element may be electrically connected with the oscillation amplifier circuit, and the second control voltage may be applied to the other end of the second variable capacitance element.

The correction circuit needs to have a characteristic by which the frequency variation characteristic of the oscillation amplifier circuit is reduced, and the correction circuit of the oscillation circuit according to this application example realizes this with the second control voltage generated based on the power supply voltage and the first control voltage. The second control voltage is applied to a terminal (the other end) of the second variable capacitance element not connected with the oscillation amplifier circuit. In this case, even when the correction circuit cannot use, for example, the first variable capacitance element (for example, an element having a proper characteristic cannot be selected due to restrictions on design), variations in oscillation frequency can be reduced by adjusting the voltage to be applied to the second variable capacitance element.

### APPLICATION EXAMPLE 7

In the oscillation circuit according to the application example described above, the correction circuit may include a selection circuit and a plurality of variable capacitance elements, one end of the selection circuit and one ends of the plurality of variable capacitance elements being electrically connected with the oscillation amplifier circuit, and the selection circuit may control the application of a voltage based on the power supply voltage to the other ends of the plurality of variable capacitance elements.

The oscillation circuit according to this application example includes the selection circuit that controls the voltage to be applied to the other end of the variable capacitance element. Therefore, it is possible to easily select the voltage (for example, the power supply voltage, a regulator voltage, or the like) to be applied to the other ends of the plurality of variable capacitance elements. This makes it possible to adjust the capacitance-voltage characteristic of a variable capacitance circuit including a plurality of variable capacitance elements, so that the frequency variation characteristic can be properly adjusted to reduce variations in oscillation frequency.

### APPLICATION EXAMPLE 8

A method for manufacturing an oscillation circuit according to this application example is a method for manufacturing an oscillation circuit including an oscillation amplifier circuit that causes an oscillating element to oscillate to generate an oscillation signal, and a correction circuit including a variable capacitance circuit whose one end is electrically connected with the oscillation amplifier circuit and whose electrostatic capacitance value is controlled with a power supply voltage, the method comprising: inputting the power supply voltage to the oscillation amplifier circuit; measuring a frequency variation characteristic that the frequency of the oscillation signal varies in response to variations in the power supply voltage; and controlling a capacitance-voltage characteristic of the variable capacitance circuit so that the variable capacitance circuit reduces the frequency variation characteristic.

According to the method for manufacturing the oscillation circuit according to this application example, the power supply voltage is input to the oscillation amplifier circuit to measure the frequency variation characteristic, and the capacitance-voltage characteristic of the variable capacitance circuit is controlled so that the variable capacitance circuit reduces the measured frequency variation characteristic. Thus, it is possible to manufacture the oscillation circuit that can reduce variations in oscillation frequency due to variations in power supply voltage.

### APPLICATION EXAMPLE 9

An electronic apparatus according to this application example includes the oscillation circuit according to the application example described above.

### APPLICATION EXAMPLE 10

A moving object according to this application example includes the oscillation circuit according to the application example described above.

According to the electronic apparatus and the moving object according to these application examples, the oscillation circuit that generates an oscillation signal at a stable frequency even with variations in power supply voltage is included. Therefore, it is possible to realize the electronic apparatus and the moving object that have excellent stability and high reliability.

### BRIEF DESCRIPTION OF THE DRAWINGS

The invention will be described with reference to the accompanying drawings, wherein like numbers reference like elements.

FIG. 1 is a block diagram showing a vibrating device including an oscillation circuit of an embodiment.

FIG. 2 is a diagram showing a circuit configuration example of the oscillation circuit of the embodiment.

FIGS. 3A and 3B are diagrams explaining connections when using NMOS-type and PMOS-type variable capacitance elements, respectively.

FIGS. 4A and 4B are graphs showing the correspondence between Vgate and VDD in the NMOS-type and PMOS-type variable capacitance elements, respectively; and FIG. 4C is a graph exemplifying capacitance-voltage characteristics of variable capacitance elements.

FIGS. 5A and 5B are graphs exemplifying capacitance-voltage characteristics of an oscillation amplifier circuit and a correction circuit, respectively; and FIG. 5C is a graph of a capacitance-voltage characteristic obtained by combining FIGS. 5A and 5B.

FIG. 6 is a diagram showing a circuit configuration example of an oscillation circuit of a first modified example.

FIG. 7 is a diagram showing a circuit configuration example of an oscillation circuit of a second modified example.

FIG. 8 is a diagram showing a circuit configuration example of an oscillation circuit of a third modified example.

FIG. 9 is a diagram showing a circuit configuration example of an oscillation circuit of a fourth modified example.

FIG. 10 is a diagram showing a circuit configuration example of an oscillation circuit of a fifth modified example.

FIGS. 11A and 11B are diagrams each showing a circuit configuration example of a power-supply variation adjusting circuit.

FIG. 12 is a diagram showing a circuit configuration example of an oscillation circuit of a sixth modified example.

FIGS. 13A and 13B are diagrams explaining connections when using NMOS-type and PMOS-type variable capacitance elements, respectively.

FIGS. 14A and 14B are graphs showing the correspondence between Vgate and VDD in the NMOS-type and PMOS-type variable capacitance elements, respectively; and FIG. 14C is a graph exemplifying capacitance-voltage characteristics of variable capacitance elements.

FIG. 15 is a diagram showing a circuit configuration example of an oscillation circuit of a comparative example.

FIGS. 16A to 16D are diagrams showing variations in a regulator voltage, an oscillation stage current, a capacitance, and an oscillation frequency, respectively, due to variations in power supply voltage in the comparative example.

FIG. 17 is a functional block diagram of an electronic apparatus.

FIG. 18 is a diagram showing an example of the appearance of an electronic apparatus.

FIG. 19 is a diagram showing an example of a moving object.

FIG. 20 is a flowchart explaining a method for manufacturing the oscillation circuit.

### DESCRIPTION OF EXEMPLARY EMBODIMENTS

Hereinafter, preferred embodiments of the invention will be described in detail with reference to the drawings. The embodiments described below do not unduly limit the contents of the invention set forth in the appended claims. Moreover, not all of the configurations described below are indispensable constituent features of the invention.

### 1. Oscillation Circuit

### 1. 1. Overall Configuration

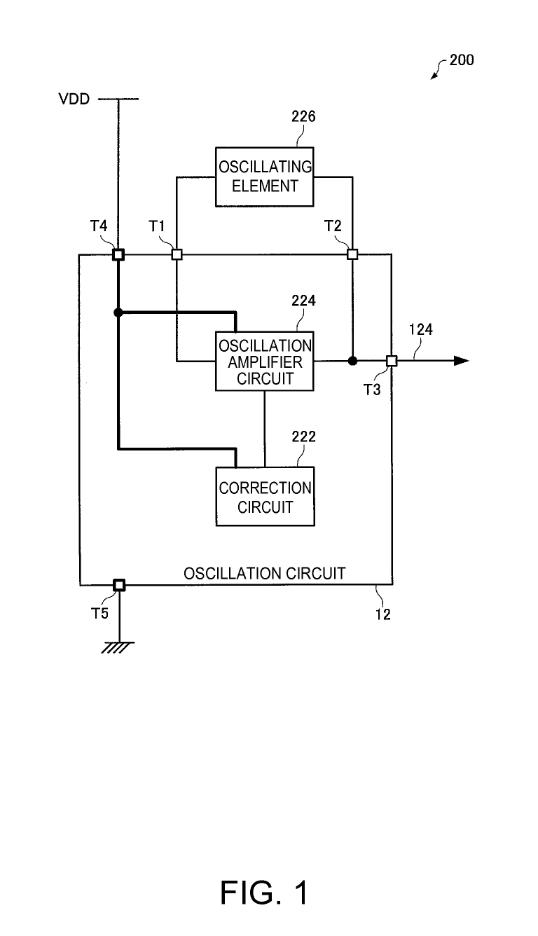

FIG. 1 is a block diagram of a vibrating device 200 including an oscillation circuit 12 of this embodiment. The oscillation circuit 12 includes an oscillation amplifier circuit 224 that causes an oscillating element 226 to oscillate to generate an oscillation signal 124, and a correction circuit 222 connected with the oscillation amplifier circuit 224. As will be described later, the correction circuit 222 is a circuit that makes corrections so as to reduce variations in the frequency of the oscillation signal 124 (hereinafter, an oscillation frequency) due to variations in a power supply voltage VDD.

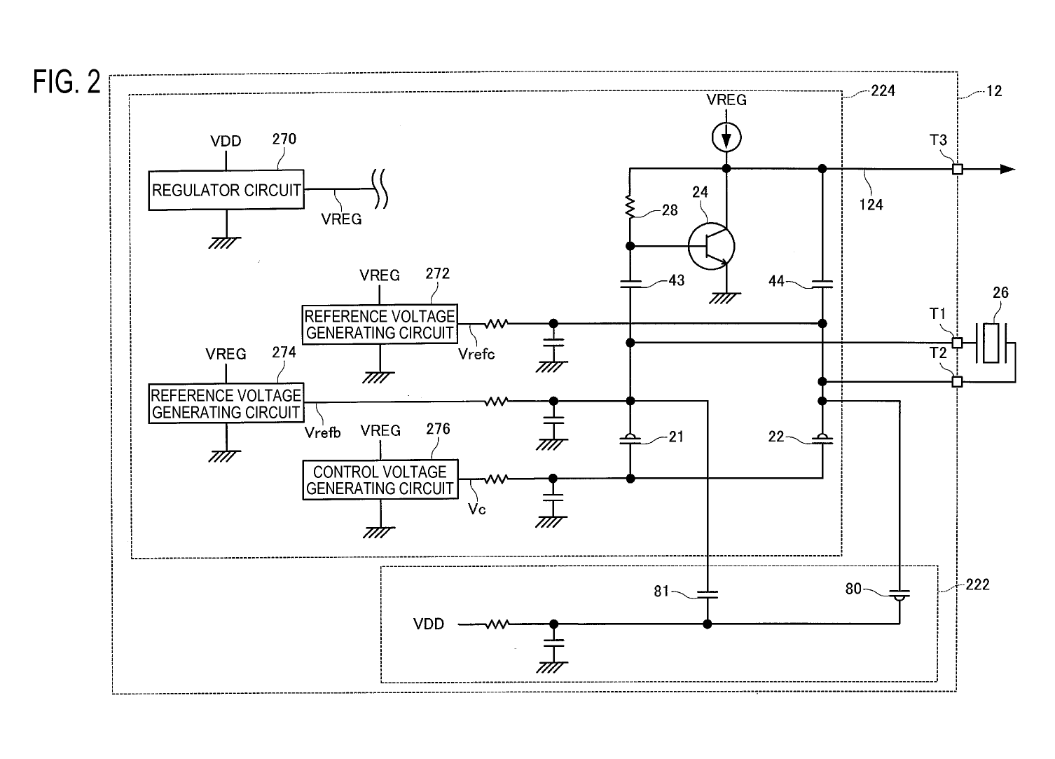

As the oscillating element 226, for example, an AT-cut quartz crystal resonator, an SC-cut quartz crystal resonator, a tuning-fork type quartz crystal resonator, a SAW (Surface Acoustic Wave) resonator, other piezoelectric resonators, a MEMS (Micro Electro Mechanical Systems) resonator, and the like can be used. In the embodiment, a description will be given of the case where the oscillating element 226 is an AT-cut quartz crystal resonator 26 (refer to FIG. 2).

The oscillation circuit 12 constitutes a portion of the vibrating device 200. Examples of the vibrating device 200 include, for example, an oscillator including a resonator as the oscillating element 226, and a physical quantity sensor including a vibration-type sensor element as the oscillating element 226. Examples of the oscillator include a piezoelectric oscillator (quartz crystal oscillator or the like) such as a temperature compensated oscillator (TCXO), a voltage controlled oscillator (VCO), or an oven controlled oscillator (OCXO), a SAW oscillator, a silicon oscillator, and an atomic oscillator. Examples of the physical quantity sensor include an angular velocity sensor (gyro sensor) and an acceleration sensor. In the embodiment, a description will be given of the case where the oscillation circuit 12 constitutes a portion of a VCXO (Voltage Controlled Crystal Oscillator) as a quartz crystal oscillator that can vary the oscillation frequency with a control voltage.

As in FIG. 1, the oscillation circuit 12 may be made into an integrated circuit (IC), and include terminals T1 and T2 for connecting with the oscillating element 226. In this case, the oscillation circuit 12 may include a terminal T3 for outputting the oscillation signal 124 and terminals T4 and T5 for supplying the power supply voltage VDD and a ground voltage VSS, respectively, and may further include another terminal (for example, a terminal for inputting an enable signal of the oscillation circuit 12. Moreover, the oscillation circuit 12 may be integrated including the oscillating element 226 to constitute a packaged vibrating device 200.

FIG. 2 is a diagram showing a circuit configuration example of the oscillation circuit 12 of the embodiment including the oscillation amplifier circuit 224 and the correction circuit 222. The oscillation amplifier circuit 224 includes a regulator circuit 270, reference voltage generating circuits 272 and 274, a control voltage generating circuit 276, variable capacitance elements 21 and 22, a bipolar transistor 24, a feedback resistor 28, and DC cut capacitors 43 and 44. In FIG. 2 and subsequent drawings, the illustration of the terminals T4 and T5 (refer to FIG. 1) of the oscillation circuit 12 is omitted. The variable capacitance elements 21 and 22 correspond to a second variable capacitance element according to the invention.

As in FIG. 2, the oscillation amplifier circuit 224 causes the quartz crystal resonator 26 (corresponding to the oscillating element 226 in FIG. 1) connected thereto to oscillate, performs amplification with the bipolar transistor 24 that includes the feedback resistor 28 and whose emitter is grounded, and generates the oscillation signal 124. In an oscillation loop, the DC cut capacitors 43 and 44 are provided, and also, the variable capacitance elements 21 and 22 are connected. The oscillation amplifier circuit 224 can adjust the frequency of the oscillation signal 124 with changes in the capacitances of the variable capacitance elements 21 and 22. The variable capacitance element is a two-terminal element whose one end is referred to as a gate while the other end being referred to as a back gate. The variable capacitance element may be an element having three or more terminals. It is sufficient that the variable capacitance element is an element whose capacitance is variable with a difference between voltages applied to at least two terminals. Moreover, the variable capacitance elements 21 and 22 may be connected (electrically connected) with the oscillation amplifier circuit 224 via a passive component such as a resistor or a capacitor.

The regulator circuit 270 is a circuit for generating a regulator voltage VREG from the power supply voltage VDD, and, for example, a circuit (refer to JP-A-2012-039348) including an error amplifier and a transistor at an output stage can be used, but the regulator circuit 270 is not particularly limited thereto. Moreover, it is assumed that the regulator voltage VREG to be generated varies with variations in the power supply voltage VDD.

The reference voltage generating circuits 272 and 274 and the control voltage generating circuit 276 are circuits that generate reference voltages Vrefc and Vrefb and a control voltage Vc, respectively, from the regulator voltage VREG. The reference voltages Vrefc and Vrefb are reference voltages to be applied to gates (back gates when the polarity is reversed) of the variable capacitance elements 22 and 21, respectively. The control voltage Vc is applied to back gates (gates when the polarity is reversed) of the variable capacitance elements 22 and 21.

In the example of FIG. 2, a resistor and a bypass capacitor are provided on each of paths of the reference voltages Vrefc and Vrefb and the control voltage Vc to be applied to the gates or back gates of the variable capacitance elements 22 and 21, but a portion or all of these elements may be omitted.

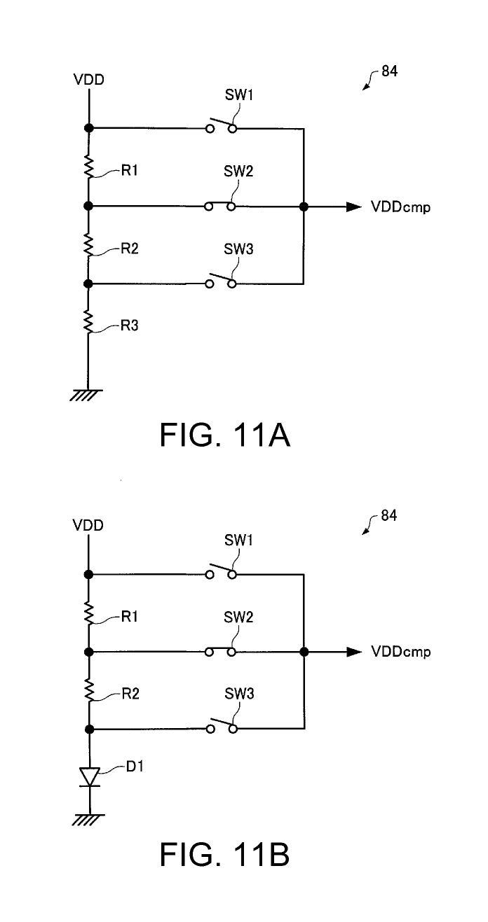

The variable capacitance element 22 has a capacitance corresponding to a voltage difference between the reference voltage Vrefc and the control voltage Vc, and the variable capacitance element 21 has a capacitance corresponding to a voltage difference between the reference voltage Vrefb and the control voltage Vc. That is, the oscillation amplifier circuit 224 can adjust the capacitances of the variable capacitance elements 22 and 21 by adjusting the control voltage Vc to adjust the frequency of the oscillation signal 124. The reference voltage generating circuits 272 and 274 each may be composed of, for example, a resistance voltage dividing circuit, but are not particularly limited thereto. Moreover, the control voltage generating circuit 276 may be composed of a resistance voltage dividing circuit including switches (refer to FIGS. 11A and 11B) like a power-supply variation adjusting circuit 84 described later, but is not particularly limited thereto.

When the power supply voltage VDD varies, the regulator voltage VREG generated from the power supply voltage VDD varies. The reference voltage generating circuits 272 and 274 and the control voltage generating circuit 276 use the regulator voltage VREG for generating the reference voltages Vrefc and Vrefb and the control voltage Vc, and a current source of the bipolar transistor 24 also uses the regulator voltage VREG. Thus, when the power supply voltage VDD varies, the capacitances of the variable capacitance elements 22 and 21 vary from a desired value, so that the frequency of the oscillation signal 124 varies. That is, the oscillation amplifier circuit 224 has a frequency variation characteristic that the oscillation frequency varies in response to variations in the power supply voltage VDD.

The oscillation circuit 12 of the embodiment includes the correction circuit 222 that reduces the frequency variation characteristic by using variations in the power supply voltage VDD. The correction circuit 222 includes a variable capacitance element 80 and a fixed capacitance element 81. The reference voltage Vrefc, which is the same as that of the variable capacitance element 22, is applied to a back gate (gate when the polarity is reversed) of the variable capacitance element 80, while the power supply voltage VDD is applied to a gate (back gate when the polarity is reversed) of the variable capacitance element 80. A capacitance-voltage characteristic of the variable capacitance element 80 will be described later. The reference voltage Vrefb, which is the same as that of the variable capacitance element 21, is applied to one end of the fixed capacitance element 81, while the power supply voltage VDD is applied to the other end. In the correction circuit 222 of the embodiment, a resistor and a bypass capacitor are provided on a path of the power supply voltage VDD to be applied to the variable capacitance element and the fixed capacitance element 81. The variable capacitance element 80 corresponds to a first variable capacitance element according to the invention. In the correction circuit 222, the circuit scale may be reduced by omitting the resistor and bypass capacitor provided on the path of the power supply voltage VDD to be applied to the variable capacitance element 80 and the fixed capacitance element 81. Moreover, the correction circuit 222 may be connected (electrically connected) with the oscillation amplifier circuit 224 via a passive component such as a resistor or a capacitor.

The variable capacitance elements 21, 22, and 80 of the oscillation circuit 12 of the embodiment are MOS-type variable capacitance elements. As the MOS-type variable capacitance element, there are an NMOS type and a PMOS type whose polarities are reversed from each other. As the variable capacitance elements 21, 22, and 80 of the oscillation circuit 12, both types can be used. In addition, there is a PN junction type (also referred to as a PN junction diode type) as the variable capacitance element. In the oscillation circuit 12 of the embodiment, however, the MOS type capable of obtaining a large capacitance change in a narrow voltage range is used. Moreover, the MOS-type variable capacitance element is similar in structure to a MOS transistor, and therefore suitable for combined use in a CMOS semiconductor integrated circuit.

### 1. 2. Comparative Example

The frequency variation characteristic (variations in oscillation frequency in response to variations in the power supply voltage VDD) of the oscillation amplifier circuit 224 will be described using a comparative example not including the correction circuit 222 of the oscillation circuit 12 of the embodiment.

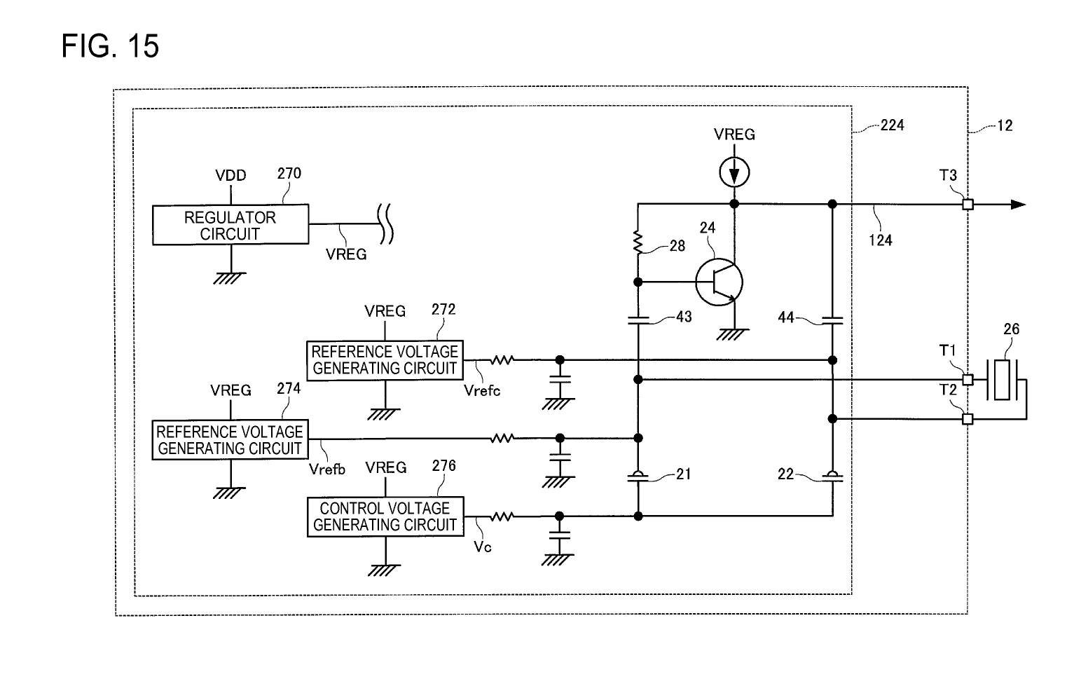

FIG. 15 is a diagram showing a circuit configuration example of an oscillation circuit of the comparative example. The oscillation circuit of the comparative example includes only the oscillation amplifier circuit 224 connected with the quartz crystal resonator 26, and does not include the correction circuit 222. The oscillation amplifier circuit 224 is the same as that of FIG. 2, and therefore, the description thereof is omitted herein.

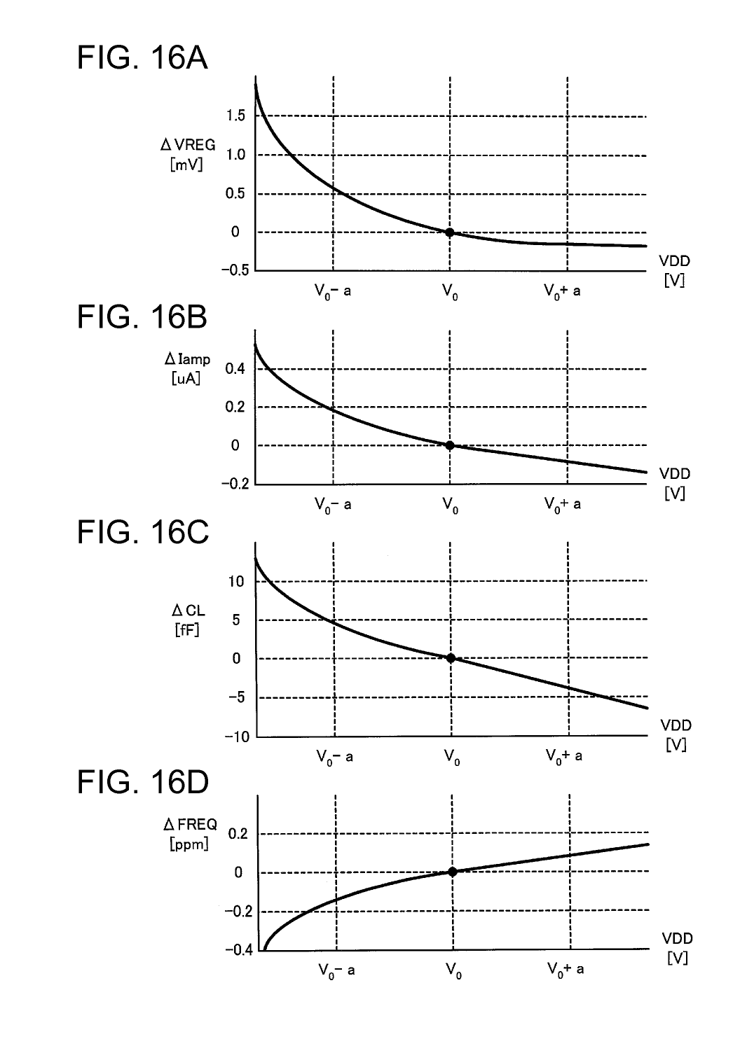

FIG. 16A is a graph showing variations (ΔVREG) in the regulator voltage VREG due to variations in the power supply voltage VDD in the oscillation circuit of the comparative example. When the power supply voltage VDD is an ideal voltage V0 (for example, 1.8 [V]) with no variation, there is no variation also in the regulator voltage VREG (ΔVREG is 0 [mV]).

However, when the power supply voltage VDD is V0−a [V] and V0+a [V] where a is a positive voltage value (for example, 0.5 [V]), ΔVREG changes to +0.6 [mV] and −0.2 [mV], respectively. That is, as shown by a characteristic curve in FIG. 16A, the regulator voltage VREG varies in response to variations in the power supply voltage VDD. Then, the reference voltages Vrefc and Vrefb and the control voltage Vc in FIG. 15 also vary.

FIG. 16B is a graph showing variations (ΔIamp) in oscillation stage current due to variations in the power supply voltage VDD in the oscillation circuit of the comparative example. The oscillation stage current is a current that flows due to amplification by the bipolar transistor 24. As in FIG. 16B, when the power supply voltage VDD decreases (for example, changes from the voltage V0 to V0−a), the amount of the current increases; while when the power supply voltage VDD increases (for example, changes from the voltage V0 to V0+a), the amount of the current decreases. When the amount of the current varies, the amplitude of the oscillation signal 124 to be amplified varies, and therefore, the capacitances of the variable capacitance elements 22 and 21 also vary. In the following, when the power supply voltage VDD varies in a decreasing direction, this is expressed in such a way that “the power supply voltage VDD varies negatively”; while when the power supply voltage VDD varies in an increasing direction, this is expressed in such a way that “the power supply voltage VDD varies positively”.

FIG. 16C is a diagram showing variations (ΔCL) in the capacitances of the variable capacitance elements 22 and 21 due to variations in the power supply voltage VDD in the oscillation circuit of the comparative example. As described above, the reference voltages Vrefc and Vrefb and the control voltage Vc vary in response to variations in the power supply voltage VDD, and the amplitude of the oscillation signal 124 also varies. Therefore, as in FIG. 16C, when the power supply voltage VDD varies negatively, the capacitance increases; while when the power supply voltage VDD varies positively, the capacitance decreases.

FIG. 16D is a diagram showing variations (ΔFREQ) in oscillation frequency in this case. Since the capacitances of the variable capacitance elements 22 and 21 vary in response to variations in the power supply voltage VDD, the oscillation frequency also varies. As in FIG. 16D, when the power supply voltage VDD varies negatively, the oscillation frequency becomes low; while when the power supply voltage VDD varies positively, the oscillation frequency becomes high. As described above, the oscillation amplifier circuit 224 of the comparative example has the frequency variation characteristic (variations in oscillation frequency in response to variations in the power supply voltage VDD).

FIGS. 16A to 16D are examples of ΔVREG, ΔIamp, ΔCL, and ΔFREQ in response to variations in the power supply voltage VDD, and ΔVREG, ΔIamp, ΔCL, and ΔFREQ may change due to a specific configuration or the like of the circuit. For example, if a specific circuit configuration of the regulator circuit 270 is different, the regulator voltage VREG may decrease when the power supply voltage VDD varies negatively, while the regulator voltage VREG may rise when the power supply voltage VDD varies positively.

### 1. 3. Correction Circuit

Here, a description will be returned to that of the oscillation circuit 12 of the embodiment again. The correction circuit 222 of the oscillation circuit 12 of the embodiment does not include, for example, a monitoring circuit and a detection circuit for monitoring and detecting variations in the power supply voltage VDD, but can reduce the frequency variation characteristic of the oscillation amplifier circuit 224 to reduce variations in oscillation frequency. The reason why the correction circuit 222 can reduce the frequency variation characteristic will be described below.

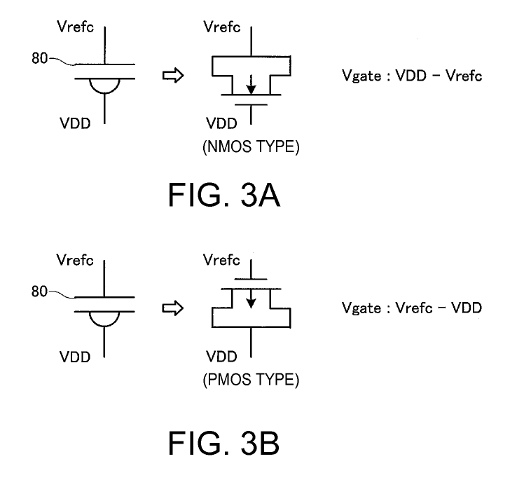

As in FIG. 2, the correction circuit 222 includes the variable capacitance element 80 to which the power supply voltage VDD and the reference voltage Vrefc are applied. As described above, the variable capacitance element 80 is a MOS-type variable capacitance element, and there are NMOS-type and PMOS-type variable capacitance elements as the MOS-type variable capacitance element. FIGS. 3A and 3B are diagrams explaining connections when using the NMOS-type and PMOS-type variable capacitance elements 80, respectively.

First, when the NMOS-type variable capacitance element is used as in FIG. 3A, the reference voltage Vrefc, which is the same as that of the variable capacitance element 22, is applied to the back gate of the variable capacitance element 80, while the power supply voltage VDD is applied to the gate of the variable capacitance element 80. Agate voltage Vgate is obtained by subtracting the voltage of the back gate from the voltage of the gate. The gate voltage Vgate in this case is “VDD−Vrefc”.

On the other hand, when the PMOS-type variable capacitance element is used as in FIG. 3B, the reference voltage Vrefc, which is the same as that of the variable capacitance element 22, is applied to the gate of the variable capacitance element 80, while the power supply voltage VDD is applied to the back gate of the variable capacitance element 80. The gate voltage Vgate in this case is “Vrefc−VDD”.

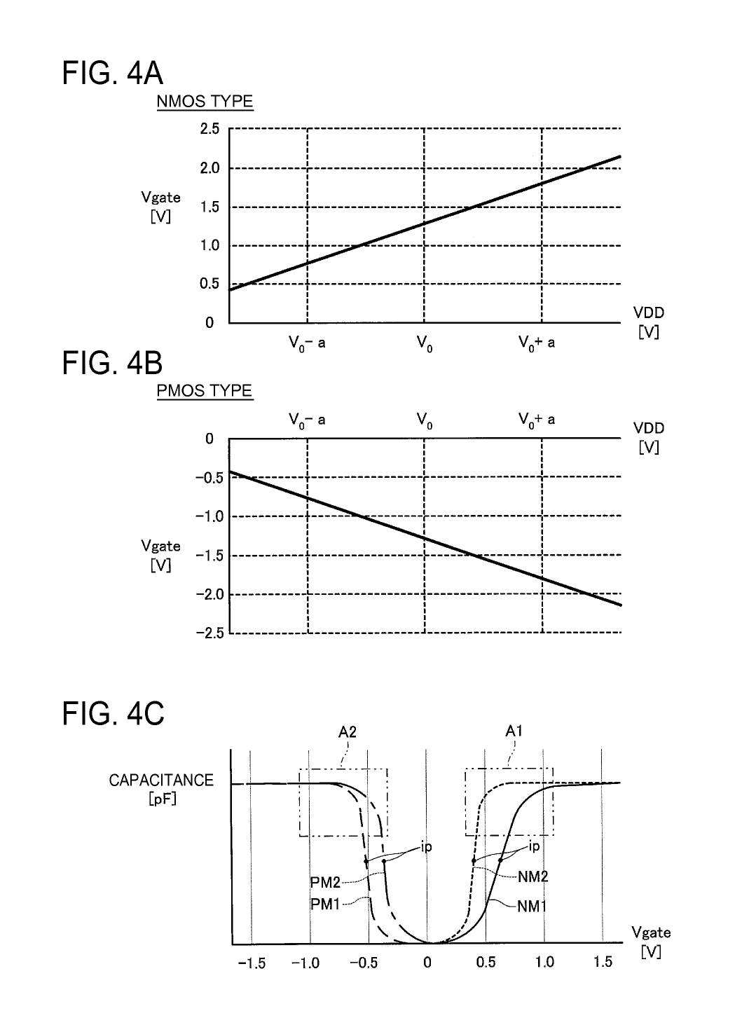

FIGS. 4A and 4B are graphs showing the correspondence between Vgate and VDD in the NMOS-type and PMOS-type variable capacitance elements, respectively. In the case of using the NMOS-type variable capacitance element as in FIG. 4A, when the power supply voltage VDD varies positively, the gate voltage Vgate also rises. On the other hand, in the case of using the PMOS-type variable capacitance element as in FIG. 4B, when the power supply voltage VDD varies positively, the gate voltage Vgate decreases.

FIG. 4C is a graph exemplifying the capacitance-voltage characteristic (C-V characteristic) of the variable capacitance element 80. The voltage (horizontal axis) herein is the gate voltage Vgate. FIG. 4C shows capacitance-voltage characteristics of four different types (NMOS type or PMOS type, or threshold) of variable capacitance elements 80. NM1 and NM2 are capacitance-voltage characteristics of two NMOS-type variable capacitance elements 80 having different thresholds. On the other hand, PM1 and PM2 are capacitance-voltage characteristics of two PMOS-type variable capacitance elements 80 having different thresholds. Each of the capacitance-voltage characteristics (NM1, NM2, PM1, and PM2) in FIG. 4C forms a curve obtained by connecting two curves having depressions (recessed portions) in different directions at an inflection point ip.

Here, a portion having a characteristic opposite to the capacitance-voltage characteristic (refer to FIG. 16C) of the variable capacitance elements 22 and 21 causing the frequency variation characteristic (refer to FIG. 16D) of the oscillation amplifier circuit 224 is to be found in FIG. 4C. Then, curve portions (hereinafter referred to as characteristic curves) of the capacitance-voltage characteristics included in an area A1 in FIG. 4C are nearly vertically symmetrical (symmetrical in a direction of the vertical axis [capacitance]) in shape to the capacitance-voltage characteristic (refer to FIG. 16C) of the variable capacitance elements 22 and 21, and therefore have opposite characteristics. For example, in the capacitance-voltage characteristic of the variable capacitance elements 22 and 21, when the power supply voltage VDD varies positively, the capacitance decreases. However, according to the characteristic curves in the area A1, when the gate voltage Vgate varies positively, the capacitances of the variable capacitance elements 80 increase.

Hence, when the variable capacitance element 80 with which such a characteristic curve can be obtained in response to variations around the voltage V0 in the power supply voltage VDD is selected, the characteristic of the variable capacitance element 80 is opposite to the capacitance-voltage characteristic of the variable capacitance elements 22 and 21. For example, it is assumed that the ideal voltage V0 with no variation is 1.8 [V] and the reference voltage Vrefc is about 1.2 [V]. In this case, variations in the power supply voltage VDD correspond to variations around 0.6 [V] (=V0−Vrefc) in Vgate in FIG. 4C. That is, in this example, the area A1 is just the area corresponding to the variations in the power supply voltage VDD. Therefore, the variable capacitance element 80 having, for example, the capacitance-voltage characteristic NM1 is selected. Then, due to the variations in the power supply voltage VDD, the capacitance of the variable capacitance element 80 varies substantially within the range of the area A1 in FIG. 4C according to the capacitance-voltage characteristic NM1 shown by a solid line.

Then, the variable capacitance element 80 described above is connected in parallel with the variable capacitance elements 22 and 21 (refer to FIG. 2). In this case, even when the power supply voltage VDD varies and the capacitances of the variable capacitance elements 22 and 21 change according to the capacitance-voltage characteristic (refer to FIG. 16C), the capacitance of the variable capacitance element 80 having the opposite characteristic changes so as to cancel out the changes in the capacitances of the variable capacitance elements 22 and 21. Therefore, the frequency variation characteristic of the oscillation amplifier circuit 224 can be favorably reduced to reduce variations in oscillation frequency due to variations in the power supply voltage.

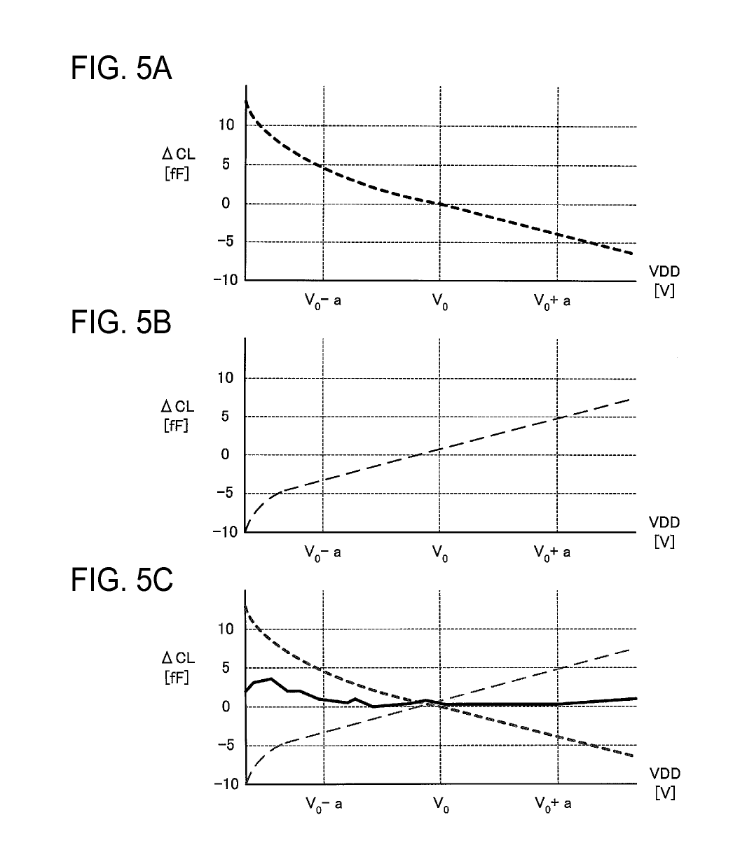

This effect will be described with reference to FIGS. 5A to 5C. FIG. 5A is a graph showing the capacitance-voltage characteristic (however, the vertical axis represents ΔCL as variations in capacitance) of the variable capacitance elements 22 and 21 of the oscillation amplifier circuit 224, which is the same drawing as FIG. 16C. FIG. 5B is a graph showing the capacitance-voltage characteristic (however, the vertical axis represents ΔCL as variations in capacitance) of the variable capacitance element 80 of the correction circuit 222. As described above herein, it is assumed that the variable capacitance element 80 having the characteristic curve of NM1 in FIG. 4C is selected. Then, the characteristic curve in FIG. 5B is close to one vertically (in a direction of the vertical axis) symmetrical to the characteristic curve in FIG. 5A.

FIG. 5C is a graph of a capacitance-voltage characteristic obtained by combining FIGS. 5A and 5B. Since the variable capacitance element 80 is provided in parallel with the variable capacitance element 22 as in FIG. 2, the capacitance-voltage characteristic of the oscillation circuit including the correction circuit 222 becomes a curve obtained by combining two dotted lines (corresponding to FIGS. 5A and 5B) and shown by a solid line in FIG. 5C. In this case, the curve shown by the solid line indicates about 0 even when VDD varies, from which it is found that the correction circuit 222 (more specifically, the variable capacitance element 80) favorably reduces the frequency variation characteristic of the oscillation amplifier circuit 224 to reduce variations in oscillation frequency due to variations in the power supply voltage.

In the above, the NMOS-type variable capacitance element 80 having a proper threshold with which the characteristic curve in the area A1 is to be selected is selected. However, a PMOS-type variable capacitance element 80 having a proper threshold with which a characteristic curve in an area A2 is to be selected may be selected. Moreover, a configuration in which the positions of the variable capacitance element 80 and the fixed capacitance element 81 are exchanged is also possible although the configuration depends on the voltage of the reference voltage Vrefb. That is, the variable capacitance element 80 may be provided in parallel with the variable capacitance element 21, and the fixed capacitance element 81 may be provided in parallel with the variable capacitance element 22. Further, although only the threshold of the variable capacitance element 21 is considered in the above, the characteristic curve may be adjusted by changing the size of the NMOS-type variable capacitance element 80 or the PMOS-type variable capacitance element 80, instead of the threshold or in addition to the threshold, so that the characteristic curve in the area A1 becomes proper.

### 1. 4. First Modified Example

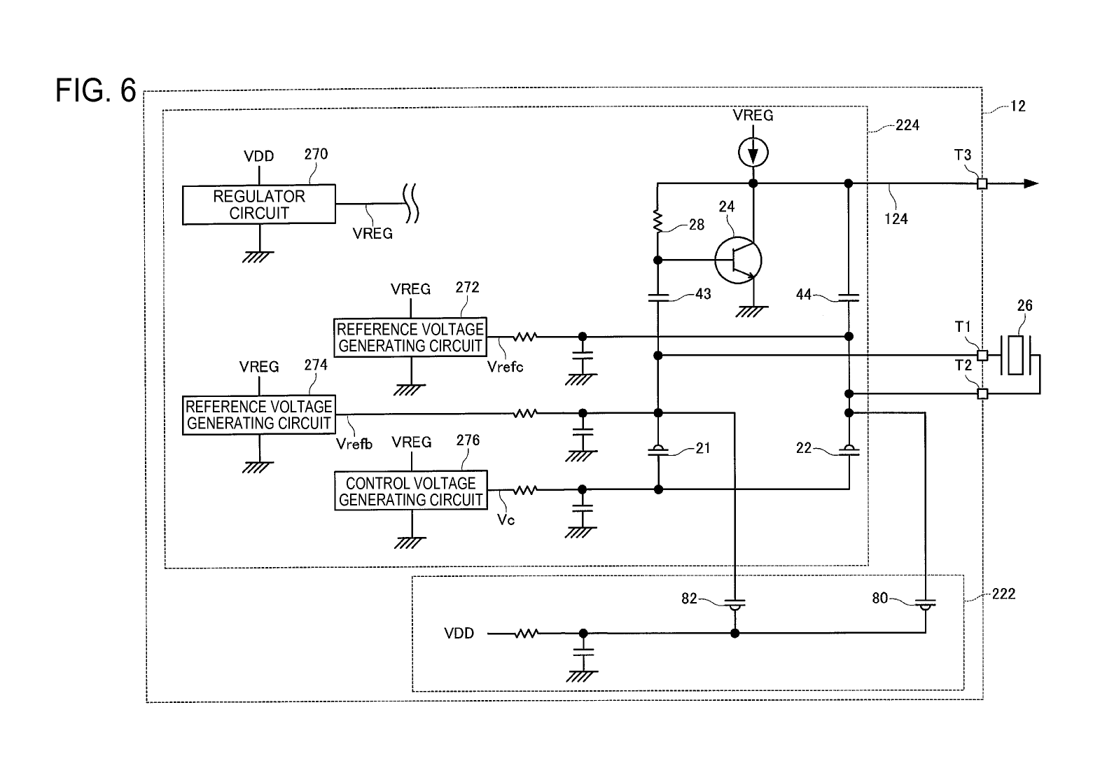

The oscillation circuit 12 of the embodiment is not limited to the above configuration, and the following modifications are possible. FIG. 6 is a diagram showing a circuit configuration example of an oscillation circuit 12 (the oscillation amplifier circuit 224 and the correction circuit 222) of a first modified example. The same elements as those of FIGS. 1 to 5 are denoted by the same reference numerals and signs, and the description thereof is omitted.

The oscillation circuit 12 of the first modified example differs from the oscillation circuit 12 of the embodiment in that a variable capacitance element 82 is used instead of the fixed capacitance element 81 in the correction circuit 222. In this case, by combining, not only the variable capacitance element 80, but also the variable capacitance element 82, it is possible to obtain a capacitance-voltage characteristic by which the frequency variation characteristic of the oscillation amplifier circuit 224 can be further reduced. That is, by combining the variable capacitance element 80 and the variable capacitance element 82, it is possible to increase the variation of the curve of the capacitance-voltage characteristic compared to the case of the variable capacitance element 80 alone. The other elements are the same as those of the oscillation circuit 12 of the embodiment, and the description thereof is omitted.

### 1. 5. Second Modified Example

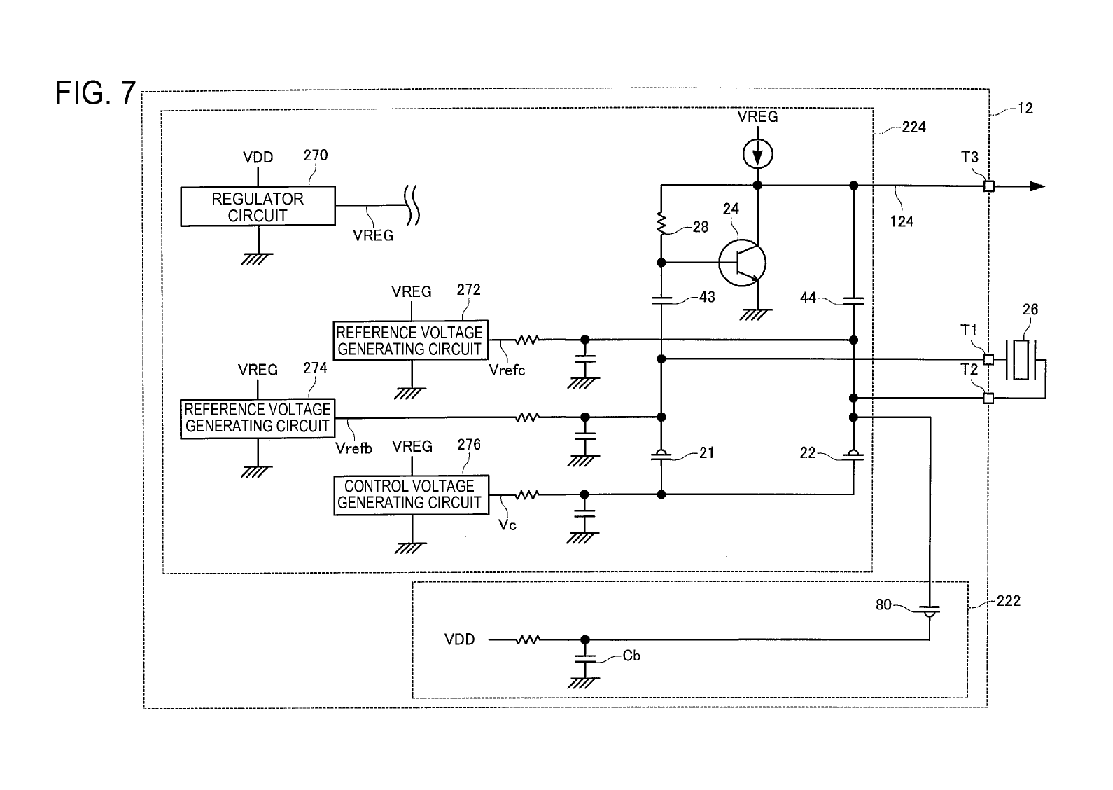

FIG. 7 is a diagram showing a circuit configuration example of an oscillation circuit 12 (the oscillation amplifier circuit 224 and the correction circuit 222) of a second modified example. The same elements as those of FIGS. 1 to 6 are denoted by the same reference numerals and signs, and the description thereof is omitted.

The oscillation circuit 12 of the second modified example differs from the oscillation circuit 12 of the embodiment in that the fixed capacitance element 81 is removed in the correction circuit 222. In this case, only the variable capacitance element 80 that substantially reduces the frequency variation characteristic of the oscillation amplifier circuit 224 is left, and the fixed capacitance element 81 that can be omitted is not used, and therefore, the circuit scale can be reduced.

In this case, the circuit scale may be further reduced by also omitting a bypass capacitor Cb provided in the correction circuit 222. The other elements are the same as those of the oscillation circuit 12 of the embodiment, and the description thereof is omitted.

### 1. 6. Third Modified Example

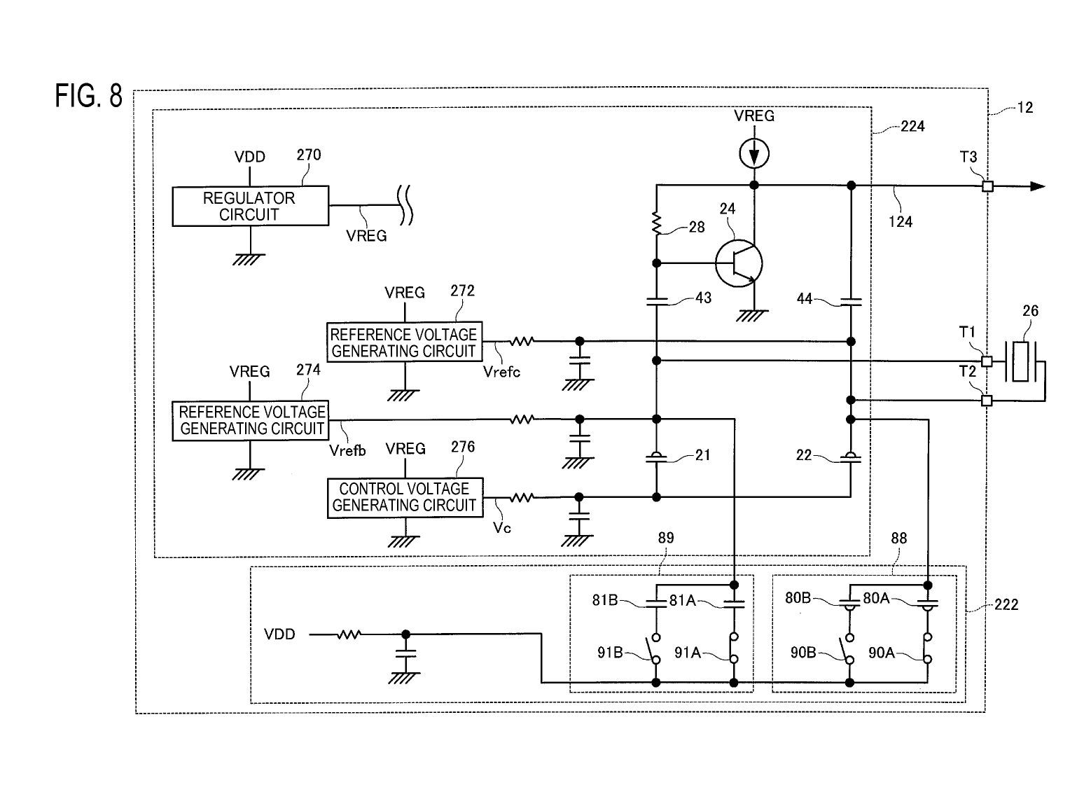

FIG. 8 is a diagram showing a circuit configuration example of an oscillation circuit 12 (the oscillation amplifier circuit 224 and the correction circuit 222) of a third modified example. The same elements as those of FIGS. 1 to 7 are denoted by the same reference numerals and signs, and the description thereof is omitted.

The oscillation circuit 12 of the third modified example differs from the oscillation circuit 12 of the embodiment in that circuits (a variable capacitance circuit 88 and a fixed capacitance circuit 89, respectively) each composed of capacitance elements connected with switches are used instead of the variable capacitance element 80 and the fixed capacitance element 81 in the correction circuit 222. In the example of FIG. 8, the variable capacitance circuit 88 of the oscillation circuit 12 of the third modified example is composed of two variable capacitance elements 80A and 80B provided in parallel. The reference voltage Vrefc is applied to back gates (gates when the polarity is reversed) of the variable capacitance elements 80A and 80B, while the power supply voltage VDD is applied to gates (back gates when the polarity is reversed) thereof via respective switches 90A and 90B.

Moreover, in the example of FIG. 8, the fixed capacitance circuit 89 of the oscillation circuit 12 of the third modified example is composed of two fixed capacitance elements 81A and 81B provided in parallel. The reference voltage Vrefb is applied to one ends of the fixed capacitance elements 81A and 81B, while the power supply voltage VDD is applied to the other ends thereof via respective switches 91A and 91B.

Each of the switches 90A, 90B, 91A, and 91B can assume an ON state (state where the power supply voltage VDD is applied) or an OFF state (state where the power supply voltage VDD is not applied) with a control signal (not shown). The control signal may be given from the outside of the oscillation circuit 12, or may be given according to the value of a register or the like inside the oscillation circuit 12.

As described above, in the oscillation circuit 12 of the embodiment in FIG. 2, it is necessary to select the variable capacitance element 80 having a proper capacitance-voltage characteristic so that a characteristic curve symmetrical to the capacitance-voltage characteristic of the variable capacitance elements 22 and 21 is obtained. However, when considering manufacturing variations or the like, it is preferable that the variable capacitance element 80 having a proper capacitance-voltage characteristic is realized by a combination of some variable capacitance elements, and that the capacitance can be adjusted in, for example, manufacturing and shipping. In the oscillation circuit 12 of the third modified example, the capacitance of the variable capacitance circuit 88 can be adjusted by the switches 90A and 90B, and the capacitance of the fixed capacitance circuit 89 can be adjusted by the switches 91A and 91B. The switches 90A and 90B correspond to a selection circuit according to the invention. The other elements are the same as those of the oscillation circuit 12 of the embodiment, and the description thereof is omitted. The variable capacitance circuit 88 and the fixed capacitance circuit 89 include one or more variable capacitance elements 80 and one or more fixed capacitance elements 81, respectively, and the number of elements is not limited to two as in the example of FIG. 8. Moreover, the fixed capacitance circuit 89 may be omitted. Further, similarly to the configuration in the first modified example, a variable capacitance circuit similar to the variable capacitance circuit 88 can be used instead of the fixed capacitance circuit 89.

### 1. 7. Fourth Modified Example

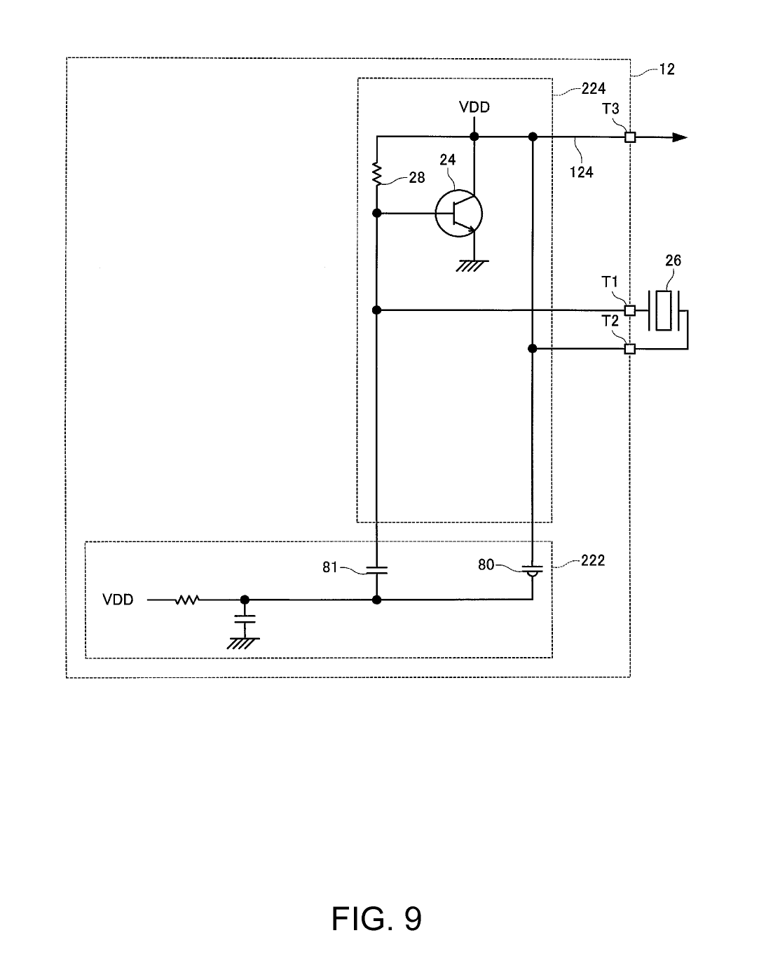

FIG. 9 is a diagram showing a circuit configuration example of an oscillation circuit 12 (the oscillation amplifier circuit 224 and the correction circuit 222) of a fourth modified example. The same elements as those of FIGS. 1 to 8 are denoted by the same reference numerals and signs, and the description thereof is omitted.

The oscillation circuit 12 of the fourth modified example differs from the oscillation circuit 12 of the embodiment in that the regulator voltage VREG is not used. The oscillation circuit 12 of the fourth modified example does not include the regulator circuit 270, and does not have the reference voltages Vrefc and Vrefb and the control voltage Vc that are generated using the regulator voltage VREG. Moreover, the oscillation amplifier circuit 224 of the fourth modified example does not include the variable capacitance elements 21 and 22, and does not have the DC cut capacitors 43 and 44. Moreover, the current source of the bipolar transistor 24 uses, not the regulator voltage VREG, but the power supply voltage VDD.

In this case, when there is no variation in the power supply voltage VDD, the oscillation amplifier circuit 224 of the fourth modified example outputs the oscillation signal 124 at a predetermined frequency. When there are variations in the power supply voltage VDD, variations in oscillation frequency can be reduced by the correction circuit 222 similarly to the oscillation circuit 12 of the embodiment. Since the regulator voltage VREG is not used in the oscillation circuit 12 of the fourth modified example, the circuit scale can be greatly reduced compared to the oscillation circuit 12 of the embodiment.

In the oscillation circuit 12 of the embodiment and the oscillation circuits 12 of the first to fourth modified examples, the power supply voltage VDD is applied to the gate or back gate of the variable capacitance element 80 (the variable capacitance element 80 and the variable capacitance element 82 in the first modified example, which are hereinafter referred to as the variable capacitance element 80 or the like) of the correction circuit 222. Therefore, compared to the case where, for example, the regulator voltage VREG is applied, the power supply voltage VDD can be directly transmitted to the variable capacitance element 80 or the like without reducing the variation amount of the power supply voltage VDD. Thus, since there is no need to increase the capacitance variable sensitivity of the variable capacitance element 80 or the like, the noise resistance can be increased.

### 1. 8. Fifth Modified Example

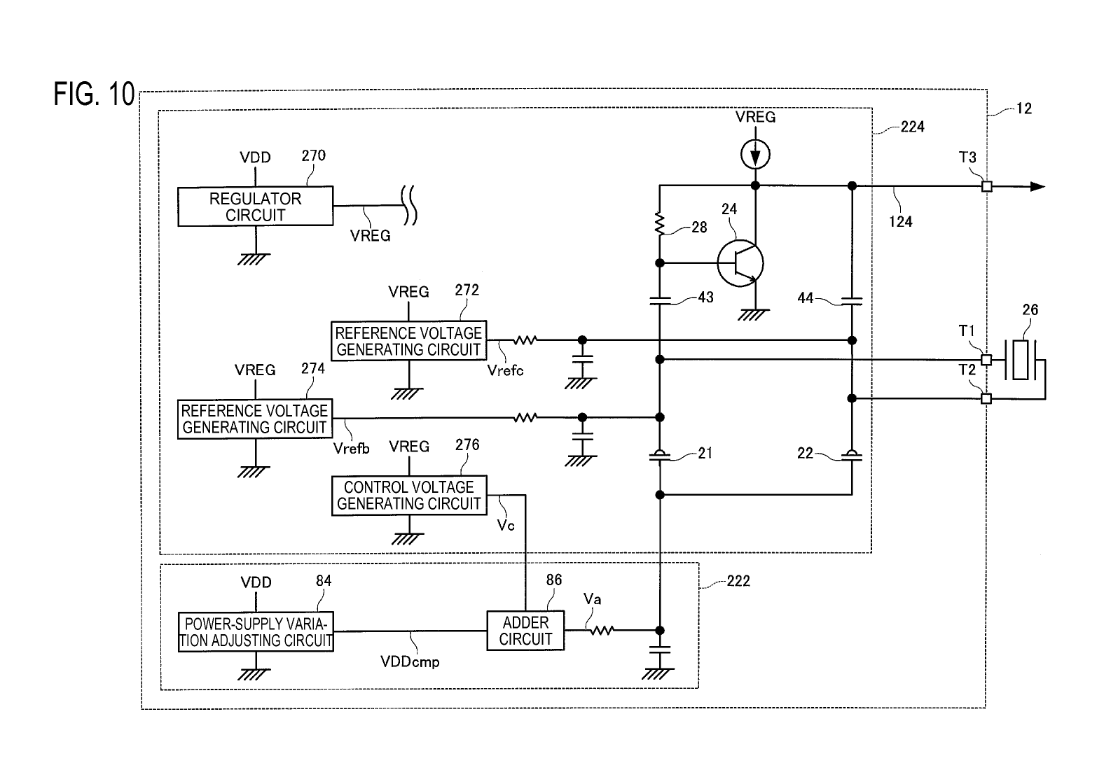

FIG. 10 is a diagram showing a circuit configuration example of an oscillation circuit 12 (the oscillation amplifier circuit 224 and the correction circuit 222) of a fifth modified example. The same elements as those of FIGS. 1 to 9 are denoted by the same reference numerals and signs, and the description thereof is omitted.

The oscillation circuit 12 of the fifth modified example differs from the oscillation circuit 12 of the embodiment in that the variable capacitance element 80 and the fixed capacitance element 81 are not included, and that an adjustment voltage VDDcmp generated by the power-supply variation adjusting circuit 84 and the control voltage Vc are added together by an adder circuit 86 to be applied to back gates (gates when the polarity is reversed) of the variable capacitance elements 21 and 22.

In the oscillation circuit 12 of the fifth modified example, the frequency variation characteristic of the oscillation amplifier circuit 224 is reduced by adjusting the control voltage Vc. In this case, the power-supply variation adjusting circuit 84 generates the adjustment voltage VDDcmp based on variations in the power supply voltage VDD, and the adder circuit 86 adds the adjustment voltage VDDcmp to the control voltage Vc to generate a control voltage Va. The control voltages Vc and Va correspond respectively to a first control voltage and a second control voltage according to the invention. As the adder circuit 86, a circuit composed of, for example, an operational amplifier and resistors that perform weighting of input voltages (the adjustment voltage VDDcmp and the control voltage Vc) can be used, but the adder circuit 86 is not particularly limited thereto.

FIGS. 11A and 11B are diagrams each showing a circuit configuration example of the power-supply variation adjusting circuit 84. The power-supply variation adjusting circuit 84 may be configured such that, as in FIG. 11A, each of voltage values of a resistance voltage dividing circuit composed of resistors R1 to R3 is selected using switches SW1 to SW3 to be used as the adjustment voltage VDDcmp. Moreover, the power-supply variation adjusting circuit 84 may have a configuration of using, not the resistor R3, but a diode D1 as in FIG. 11B. In this case, since the power-supply variation adjusting circuit 84 includes the diode D1, the power-supply variation adjusting circuit 84 can have a proper temperature characteristic by which variations due to temperature changes are suppressed. A control signal that brings the switches SW1 to SW3 into the ON or OFF state may be given from the outside of the oscillation circuit 12, or may be given according to the value of a register or the like inside the oscillation circuit 12.

In the oscillation circuit 12 of the fifth modified example, the frequency variation characteristic of the oscillation amplifier circuit 224 is reduced not by using the capacitance-voltage characteristic of the variable capacitance element 80 or the like but by adjusting the control voltage Vc. Even when the variable capacitance element 80 or the like having a proper capacitance-voltage characteristic cannot be selected due to, for example, restrictions on design, the correction circuit 222 that makes corrections corresponding to variations in the power supply voltage VDD can be configured, so that variations in oscillation frequency can be reduced.

### 1. 9. Sixth Modified Example

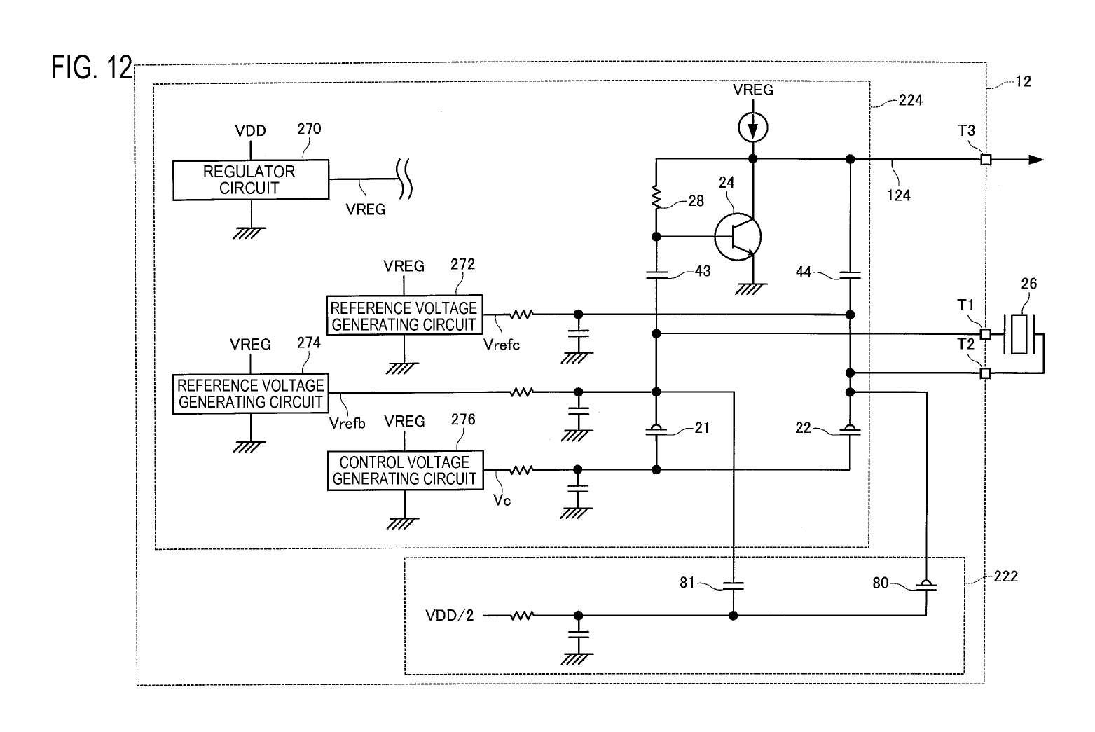

FIG. 12 is a diagram showing a circuit configuration example of an oscillation circuit 12 (the oscillation amplifier circuit 224 and the correction circuit 222) of a sixth modified example. The same elements as those of FIGS. 1 to 11 are denoted by the same reference numerals and signs, and the description thereof is omitted.

The oscillation circuit 12 of the sixth modified example differs from the oscillation circuit 12 of the embodiment in that the polarity of the variable capacitance element 80 is reversed, and that an adjusted voltage, not the power supply voltage VDD, is used in the correction circuit 222. In the example of FIG. 12, the adjusted voltage is VDD/2. VDD/2 can be generated by, for example, a resistance voltage dividing circuit (refer to FIGS. 11A and 11B).

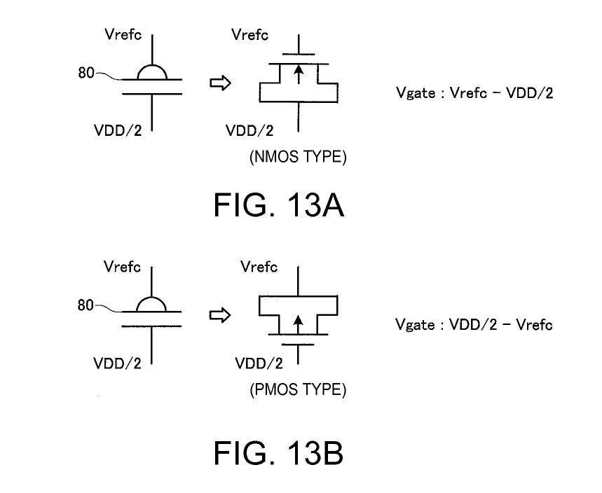

FIGS. 13A and 13B are diagrams explaining connections when using NMOS-type and PMOS-type variable capacitance elements 80, respectively, in the oscillation circuit 12 of the sixth modified example. Compared to the oscillation circuit 12 of the embodiment, the polarity of the variable capacitance element 80 is reversed. Moreover, VDD/2 is applied to a gate or a back gate. Thus, when the NMOS-type variable capacitance element is used, the gate voltage Vgate is “Vrefc−(VDD/2)” as in FIG. 13A. On the other hand, when the PMOS-type variable capacitance element is used, the gate voltage Vgate is “(VDD/2)−Vrefc” as in FIG. 13B.

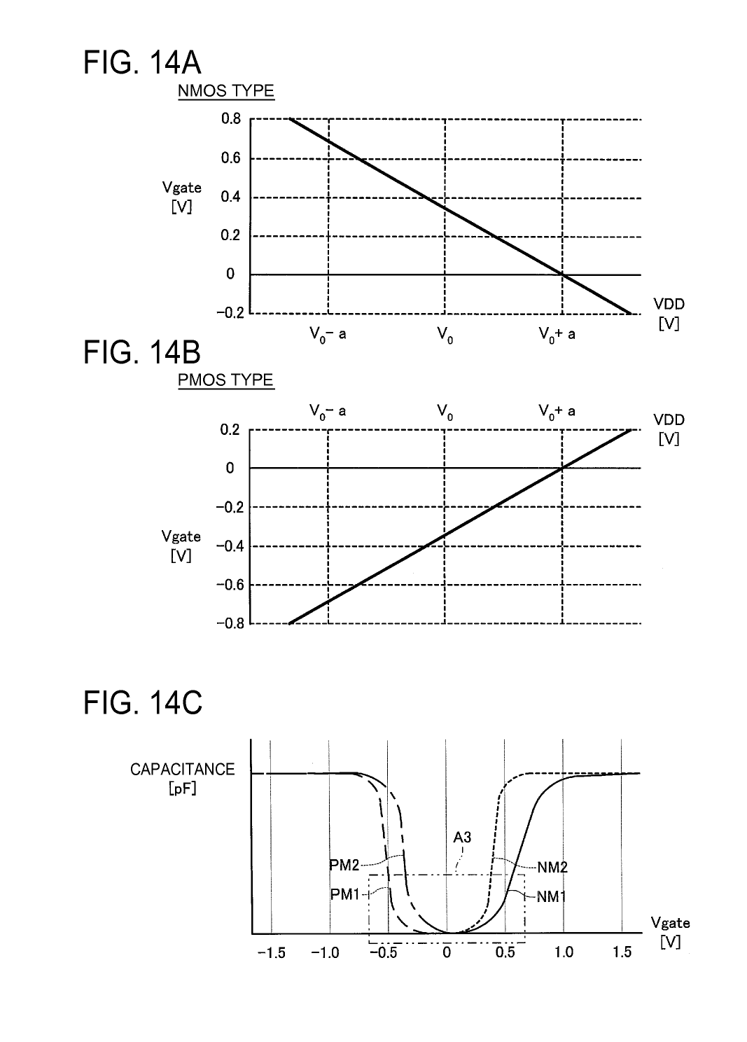

FIGS. 14A and 14B are graphs showing the correspondence between Vgate and VDD in the NMOS-type and PMOS-type variable capacitance elements, respectively. In the oscillation circuit 12 of the sixth modified example, VDD/2 as a voltage adjusted by the correction circuit 222 is applied to the variable capacitance element 80. Therefore, as in FIGS. 14A and 14B, variations around the voltage V0 in the power supply voltage VDD can correspond to variations near 0 [V] in the gate voltage Vgate of the variable capacitance element 80.

FIG. 14C is a graph exemplifying a capacitance-voltage characteristic (C-V characteristic) of the variable capacitance element 80, in which the reference numerals and signs, and the characteristic curves are the same as those of FIG. 4C, and therefore, the description thereof is omitted. In the oscillation circuit 12 of the sixth modified example, different from the oscillation circuit 12 of the embodiment, the frequency variation characteristic of the oscillation amplifier circuit 224 is reduced by using a characteristic curve included in an area A3, so that variations in oscillation frequency can be reduced. This is because, as described above, since the variations around the voltage V0 in the power supply voltage VDD correspond to the variations near 0 [V] in the gate voltage Vgate of the variable capacitance element 80, changes in the capacitance of the variable capacitance element 80 in response to variations in the power supply voltage VDD follow the characteristic curve in the area A3. For example, when the voltage V0 is 1.8 [V] and the reference voltage Vrefc is about 1.2 [V], variations in the power supply voltage VDD correspond to variations around 0.3 [V] (=Vrefc−V0/2) in Vgate in FIG. 14C.

The direction of the depression (recessed portion) is different between the characteristic curves in the areas A1 and A2 (refer to FIG. 4C) and the characteristic curve in the area A3. Thus, the characteristic curve in the area A3 needs to be reversed upside down (in the direction of the vertical axis [capacitance]) in use. Hence, the polarity of the variable capacitance element 80 is reversed in use in the oscillation circuit 12 of the sixth modified example compared to the oscillation circuit 12 of the embodiment.

In the oscillation circuit 12 of the sixth modified example, the characteristic curve in the area different from that of the oscillation circuit 12 of the embodiment can be used as shown in FIG. 14C. Hence, by using in combination the selecting method of the characteristic curve in the oscillation circuit 12 of the sixth modified example, flexibility in combination of the variable capacitance circuit 88 for further reducing the frequency variation characteristic of the oscillation amplifier circuit 224 is increased.

As described above, according to the oscillation circuits 12 of the embodiment and first to sixth modified examples, the correction circuit 222 that reduces the frequency variation characteristic of the oscillation amplifier circuit 224 by using variations in the power supply voltage VDD is included, so that variations in oscillation frequency can be reduced. In this case, the correction circuit 222 corrects the frequency variation characteristic but does not monitor the power supply voltage VDD, and therefore does not cause a problem of an increase in consumption current or circuit area. Moreover, for example, even with a circuit configuration including a monitoring circuit and a boost circuit for a regulator voltage, when the oscillation frequency changes with variations in the voltage of the boost circuit due to variations in the power supply voltage VDD, variations in oscillation frequency can be reduced with the use of the correction circuit 222.

### 2. Electronic Apparatus

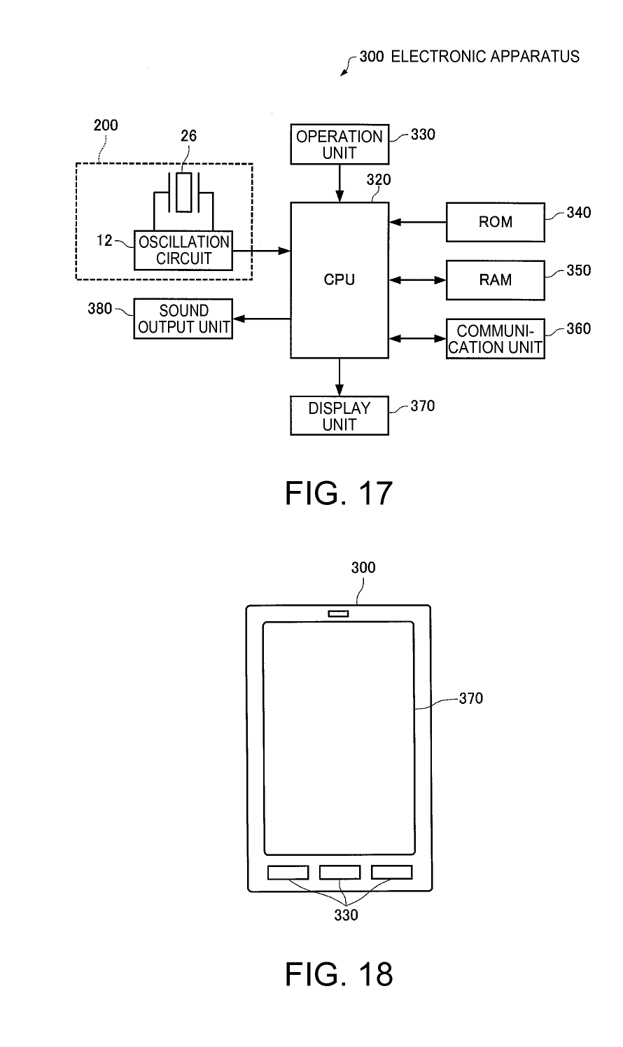

An electronic apparatus 300 of this embodiment will be described with reference to FIGS. 17 and 18. The same elements as those of FIGS. 1 to 16 are denoted by the same reference numerals and signs, and the description thereof is omitted.

FIG. 17 is a functional block diagram of the electronic apparatus 300. The electronic apparatus 300 is configured to include the vibrating device 200 including the oscillation circuit 12 and the quartz crystal resonator 26, a CPU (Central Processing Unit) 320, an operation unit 330, a ROM (Read Only Memory) 340, a RAM (Random Access Memory) 350, a communication unit 360, a display unit 370, and a sound output unit 380. In the electronic apparatus 300, a portion of the constituent elements (parts) shown in FIG. 17 may be omitted or changed, or a configuration to which another constituent element is added may be employed.

The vibrating device 200 supplies a clock pulse not only to the CPU 320 but to the parts (illustration is omitted). The vibrating device 200 may be an oscillator including the oscillation circuit 12 and the quartz crystal resonator 26 that are integrated and made into a package.

The CPU 320 performs, according to programs stored in the ROM 340 or the like, various kinds of computing processing or control processing using the clock pulse output by the oscillation circuit 12. Specifically, the CPU 320 performs various kinds of processing according to an operation signal from the operation unit 330, processing for controlling the communication unit 360 for performing data communication with the outside, processing for transmitting a display signal for causing the display unit 370 to display various kinds of information, processing for causing the sound output unit 380 to output various kinds of sounds, and the like.

The operation unit 330 is an input device composed of an operating key, a button switch, and the like, and outputs an operation signal according to a user's operation to the CPU 320.

The ROM 340 stores programs, data, and the like for the CPU 320 to perform various kinds of computing processing or control processing.

The RAM 350 is used as a working area of the CPU 320, and temporarily stores programs or data read from the ROM 340, data input from the operation unit 330, the results of operations executed by the CPU 320 according to various kinds of programs, and the like.

The communication unit 360 performs various kinds of controls for establishing data communication between the CPU 320 and an external device.

The display unit 370 is a display device composed of an LCD (Liquid Crystal Display) or the like, and displays various kinds of information based on the display signal input from the CPU 320.

The sound output unit 380 is a device that outputs sounds, such as a speaker.

As described above, the oscillation circuit 12 included in the vibrating device 200 generates the oscillation signal 124 as a clock pulse, and can reduce variations in oscillation frequency even when the power supply voltage VDD varies. That is, even when the power supply voltage VDD varies, a stable clock pulse can be supplied. Therefore, since the electronic apparatus 300 includes the oscillation circuit 12, operating stability or reliability can be increased.

As the electronic apparatus 300, various electronic apparatuses are considered. For example, examples thereof include personal computers (for example, mobile personal computers, laptop personal computers, and tablet personal computers), mobile terminals such as mobile phones, digital still cameras, inkjet ejection apparatuses (for example, inkjet printers), storage area network apparatuses such as routers or switches, local area network apparatuses, apparatuses for mobile terminal base station, television sets, video camcorders, video recorders, car navigation systems, pagers, electronic notebooks (including those with communication function), electronic dictionaries, calculators, electronic gaming machines, game controllers, word processors, workstations, videophones, surveillance TV monitors, electronic binoculars, POS terminals, medical devices (for example, electronic thermometers, sphygmomanometers, blood glucose meters, electrocardiogram measuring systems, ultrasonic diagnosis apparatuses, and electronic endoscopes), fishfinders, various kinds of measuring instrument, indicators (for example, indicators used in vehicles, aircraft, and ships), flight simulators, head-mounted displays, motion tracing, motion tracking, motion controllers, and PDR (pedestrian dead reckoning).

FIG. 18 is a diagram showing an example of the appearance of a smartphone as an example of the electronic apparatus 300. The smartphone as the electronic apparatus 300 includes buttons as the operation units 330, and an LCD as the display unit 370. Since the smartphone as the electronic apparatus 300 includes the oscillation circuit 12, operating stability or reliability can be increased.

### 3. Moving Object

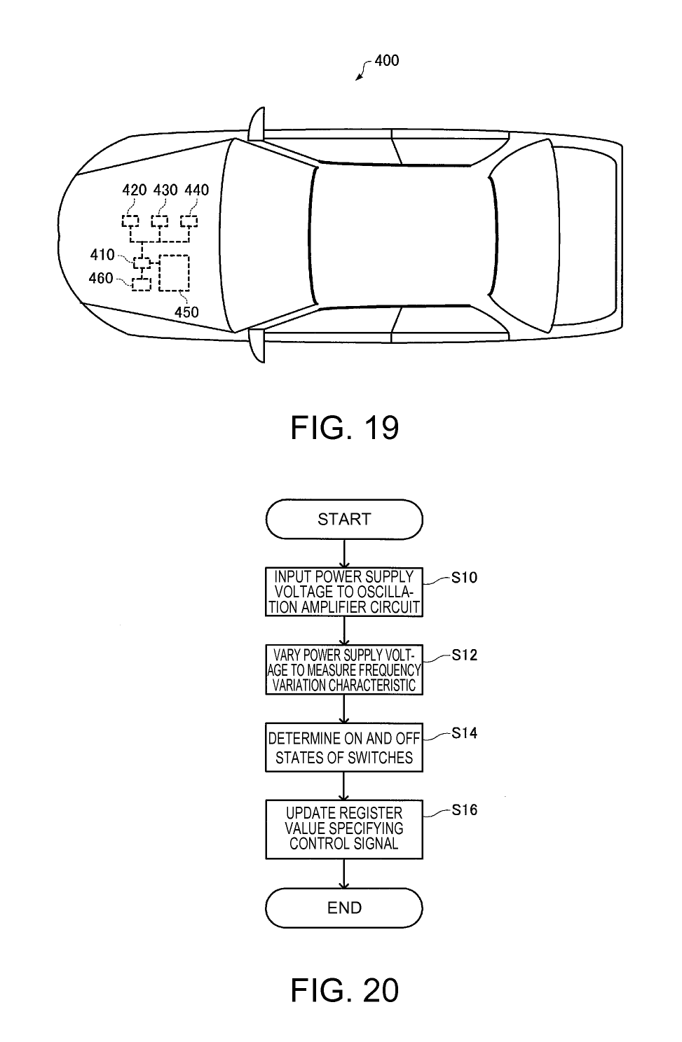

A moving object 400 of this embodiment will be described with reference to FIG. 19. FIG. 19 is a diagram (top view) showing an example of the moving object of the embodiment. The moving object 400 shown in FIG. 19 is configured to include an oscillation circuit 410, controllers 420, 430, and 440 that perform various kinds of controls for an engine system, a brake system, a keyless entry system, and the like, a battery 450, and a backup battery 460. In the moving object of the embodiment, a portion of the constituent elements (parts) in FIG. 19 may be omitted or changed, or a configuration to which another constituent element is added may be employed.

The oscillation circuit 410 corresponds to the oscillation circuit 12, and is connected with the oscillating element 226 (not shown) in use. However, the oscillation circuit 410 may be replaced with the vibrating device 200 (oscillator). Although a detailed description of the other constituent elements is omitted, high reliability is required to perform controls necessary for the movement of the moving object. For example, reliability is increased by including the backup battery 460 in addition to the battery 450.

The clock pulse output by the oscillation circuit 410 needs to be at a predetermined oscillation frequency irrespective of variations in the power supply voltage VDD.

In this case, the oscillation circuit 410 can reduce variations in oscillation frequency even when the power supply voltage VDD varies as described above. Therefore, since the systems of the moving object 400 can use a stable clock pulse even when the power supply voltage VDD varies, operating stability or reliability can be increased.

As the moving object 400, various moving objects are considered. For example, examples thereof include automobiles (including electric automobiles), aircraft such as jets or helicopters, ships, rockets, and artificial satellites.

### 4. Method for Manufacturing Oscillation Circuit

FIG. 20 is a flowchart explaining a method for manufacturing the oscillation circuit 12 described above. In this example, a description will be given of the case where the oscillation circuit 12 of the third modified example including the variable capacitance circuit 88 in the correction circuit 222 is manufactured. As in FIG. 8, the variable capacitance circuit 88 includes the variable capacitance elements 80A and 80B to which the power supply voltage VDD is applied via the switches 90A and 90B. Therefore, the capacitance-voltage characteristic of the variable capacitance circuit 88 is adjusted by switching the switches 90A and 90B between the ON and OFF states to favorably reduce the frequency variation characteristic of the oscillation amplifier circuit 224, so that variations in oscillation frequency due to variations in power supply voltage can be reduced. The flowchart in FIG. 20 explains procedures of this adjustment when performed in a manufacturing process of the oscillation circuit 12.

First, the power supply voltage VDD is input to the oscillation amplifier circuit 224 (S10). Then, the power supply voltage VDD is varied with, for example, a tester or the like used in the manufacturing process to measure the frequency variation characteristic of the oscillation amplifier circuit 224 (S12). For example, the frequency variation characteristic can be obtained by measuring the frequency of the oscillation signal 124 while the power supply voltage VDD is varying. In Step S10 and Step S12, the correction circuit 222 needs to be controlled so as not to operate. For example, a switch or the like (not shown) that electrically connects the oscillation amplifier circuit 224 with the correction circuit 222 may be provided and brought into the OFF state during Step S10 and Step S12.

Next, the capacitance-voltage characteristic of the variable capacitance circuit 88 is adjusted. That is, the ON and OFF states of the switches 90A and 90B (refer to FIG. 8) are determined so that the frequency variation characteristic of the oscillation amplifier circuit 224 can be reduced (S14). This determination may be executed by, for example, a controller (not shown) included in the correction circuit 222 according to programs, or may be executed by the tester used in the manufacturing process.

The ON and OFF states of the switches 90A and 90B (refer to FIG. 8) are determined by a control signal. The control signal may be given from the outside of the oscillation circuit 12, but it is assumed in this example that the control signal is given according to the value of the register inside the oscillation circuit 12. Then, the value corresponding to the ON or OFF state determined in Step S14 is written into the register. That is, the register value specifying the control signal is updated (S16). For example, the controller (not shown) included in the correction circuit 222 may update the register value, or the tester used in the manufacturing process may update the register value.

As described above, the power supply voltage is input to the oscillation amplifier circuit 224 to measure the frequency variation characteristic (Step S10 and Step S12), and an adjustment is made so that the variable capacitance circuit 88 has a capacitance-voltage characteristic by which the frequency variation characteristic is reduced with variations in the power supply voltage VDD (S14 and S16). Therefore, it is possible to manufacture the oscillation circuit 12 that reduces variations in oscillation frequency due to variations in the power supply voltage.

### 5. Others

The invention includes a configuration (for example, a configuration having the same function, method, and result, or a configuration having the same advantage and effect) that is substantially the same as those described in the embodiments. Moreover, the invention includes a configuration in which a non-essential portion of the configurations described in the embodiments is replaced. Moreover, the invention includes a configuration providing the same operational effects as those described in the embodiments, or a configuration capable of achieving the same advantages. Moreover, the invention includes a configuration in which a publicly known technique is added to the configurations described in the embodiments.

The entire disclosure of Japanese Patent Application No. 2013-195282, filed Sep. 20, 2013 is expressly incorporated by reference herein.

What is claimed is:

1. An oscillation circuit comprising:
an oscillation amplifier circuit that generates an oscillation signal and has a frequency variation characteristic that the frequency of the oscillation signal varies in response to variations in power supply voltage; and
a correction circuit that corrects the frequency variation characteristic with variations in the power supply voltage.

2. The oscillation circuit according to claim 1, wherein
the correction circuit includes a first variable capacitance element, and
the first variable capacitance element has a capacitance-voltage characteristic by which the frequency variation characteristic is reduced in response to variations in the power supply voltage.

3. The oscillation circuit according to claim 2, wherein
the oscillation amplifier circuit includes a second variable capacitance element,
one end of the second variable capacitance element is electrically connected with the oscillation amplifier circuit, and
the first variable capacitance element is controlled so that changes in the capacitance thereof are opposite to variations in the capacitance of the second variable capacitance element due to variations in the power supply voltage.

4. The oscillation circuit according to claim 2, wherein
the power supply voltage is applied to one end of the first variable capacitance element.

5. The oscillation circuit according to claim 3, wherein
the power supply voltage is applied to one end of the first variable capacitance element.

6. The oscillation circuit according to claim 1, wherein
the oscillation amplifier circuit includes a second variable capacitance element,
the correction circuit generates a second control voltage based on the power supply voltage and a first control voltage,
one end of the second variable capacitance element is electrically connected with the oscillation amplifier circuit, and
the second control voltage is applied to the other end of the second variable capacitance element.

7. The oscillation circuit according to claim 1, wherein
the correction circuit includes a selection circuit and a plurality of variable capacitance elements, one end of the selection circuit and one ends of the plurality of variable capacitance elements being electrically connected with the oscillation amplifier circuit, and
the selection circuit controls the application of a voltage based on the power supply voltage to the other ends of the plurality of variable capacitance elements.

8. A method for manufacturing an oscillation circuit including an oscillation amplifier circuit that causes an oscillating element to oscillate to generate an oscillation signal, and a correction circuit including a variable capacitance circuit whose one end is electrically connected with the oscillation amplifier circuit and whose electrostatic capacitance value is controlled with a power supply voltage, the method comprising:
inputting the power supply voltage to the oscillation amplifier circuit;
measuring a frequency variation characteristic that the frequency of the oscillation signal varies in response to variations in the power supply voltage; and
controlling a capacitance-voltage characteristic of the variable capacitance circuit so that the variable capacitance circuit reduces the frequency variation characteristic.

9. An electronic apparatus comprising the oscillation circuit according to claim 1.

10. A moving object comprising the oscillation circuit according to claim 1.
